(19) United States
(12) Patent Application Publication
(10) Pub. No.: US 2025/0237964 A1
(43) Pub. Date: Jul. 24, 2025

(54) METHOD AND APPARATUS FOR LASER LITHOGRAPHIC FABRICATION OF SURFACE RELIEF STRUCTURES UTILIZING OPTICAL POLARIZATION PROJECTION AND CONTINUOUSLY MOVING PHOTOMECHANICAL AZOPOLYMER FILMS

(71) Applicants: David John McGee, Bethlehem, PA (US); Jonas Strobelt, Berlin (DE)

(72) Inventors: David John McGee, Bethlehem, PA (US); Jonas Strobelt, Berlin (DE)

(21) Appl. No.: 18/421,442

(22) Filed: Jan. 24, 2024

(51) Int. Cl. G03F 7/00; G02B 5/18

(52) U.S. Cl. CPC G03F 7/70308; G02B 5/1857; G03F 7/70025; G03F 7/70291; G03F 7/70316; G03F 7/70358; G03F 7/70525; G03F 7/70725

(57) ABSTRACT

Systems and methods for generating a pattern on an azopolymer film surface is provided. The method may comprise positioning an azopolymer film onto a motorized stage of a laser optical lithography system, setting a desired period, amplitude, and size of surface relief grating to be printed onto a surface of the azopolymer film, and printing an image onto the surface of the azopolymer film. Printing the image may comprise generating spatially uniform linearly polarized light, expanding and collimating the linearly polarized light, converting the linearly polarized light to circularly polarized light, converting the circularly polarized light to elliptically polarized light, converting the elliptically polarized light from a spatial light modulator (SLM) to a final desired linearly polarized light, focusing the linearly polarized light onto the surface of the azopolymer film, and moving the azopolymer film in relation to the final desired linearly polarized light, using the motorized stage.

### TECHNICAL FIELD

Embodiments of the present disclosure relate, generally, to optical lithography and, in particular, to polarized optical lithography in which an optical polarization creates a topographical distortion on a photosensitive film surface.

### BACKGROUND

During laser optical lithography, a laser light source illuminates a photoresponsive film to create a topographical distortion of a film surface. The topographical distortion is referred to as a surface relief grating (SRG) or optical microstructure and is typically, but not always, a periodic structure.

The height of typical SRGs can vary from 1 nm to several micrometers, and the period can vary from 500 nm to 10 microns, depending on the target application. Such SRGs created on the film are then replicated through a separate process known as imprint lithography for volume reproduction. A wide variety of optical devices employ such replicated SRGs, including, e.g., spectrometers, virtual reality displays, and anti-counterfeiting devices. In some applications, the peak-to-peak surface height of the SRG is important, whereas in others the periodicity of the SRG plays a major role.

Currently employed methods for laser optical lithographic production of SRGs generally utilize either laser interferometry (LI) or optically diffractive (OD) processes. In LI, a laser beam is divided into multiple sub-beams using partially reflecting/transmitting mirrors. The sub-beams (called writing beams) are then recombined at a predetermined angle of intersection onto the surface of the photoresponsive film. This process, also known as holographic interferometry, produces high-quality SRGs with precise periodicity and low light scattering. Exposure times are relatively short, on the order of seconds to hours. The area of the SRG written is the area of the intersecting laser beams on the film surface, and is typically on the order of approximately 2 mm². For larger area structures, the laser beams can be optically expanded. However, this adds experimental complexity to correct for distortions in the expanded optical wavefronts due to the additional optical components.

A separate approach is to mechanically scan the film while under exposure to the writing beams. This approach is effective, but requires complex optical, electronic, and mechanical feedback systems to control and correct the film location in the proper writing beam location during the exposure process.

One major disadvantage of LI is the need for highly coherent laser sources and a mechanically stable environment. To create stable interference patterns on the film surface, the laser light source must typically be in a single-longitudinal mode, which is expensive compared to more common laser sources. Likewise, the mechanical environment must be free from micrometer-scale vibrations during exposure, requiring the optical setup to be mounted on large and heavy benches floating on compressed air bladders and isolated from thermal and acoustic variations as well. A separate limiting constraint on LI is that a given mechanical arrangement of the experiment produces an SRG of a single, fixed periodicity. To change the period, shape, and/or orientation of that SRG requires a change in the intersection angle of the writing laser beams. This necessitates a complete and time-intensive optomechanical realignment.

OD processes provide an alternative method for SRG fabrication. These employ the same physical idea as LI, except that the division of the laser beam into sub-beams is accomplished with a diffractive element, such as, e.g., a diffractive grating or spatial light modulator (SLM). This considerably relaxes the environmental stability requirements inherent in LI processes. Perhaps most advantageous is that OD processes employing an SLM do not require optomechanical realignment to vary the SRG period.

The SLM is a programmable diffractive element that can divide a laser beam into multiple sub-beams for writing with a user-defined intersection angle and orientation. Optically diffractive lithography using an SLM can produce SRGs of approximately the same area as for LI processes. However, given the pixel resolution of SLMs, it is generally not possible to generate larger area structures by simply expanding the writing beam, as is the case for LI processes. For larger area structures, the film and/or writing beams must be mechanically scanned.

Common to both LI and OD processes is the photoresponsive film, which is typically a photoresist deposited with a thickness on the order of micrometers on top of a glass or silicon substrate. Those portions of the film exposed to light during the exposure process undergo a photochemical change, which is subsequently converted to a topographical surface pattern by post-exposure chemical processing. Extensive research on photoresist materials has established well-known relationships among exposure time, light intensity on the film, post-exposure chemical processing, and the surface features of the final SRG such as shape and depth. As a general guide, the peak-to-peak surface height of an SRG scales with the optical exposure dosage, which is related to the optical intensity of the writing laser beams.

There are multiple common factors that limit more widespread use of LI and OD lithographic processes. Because the films used in these processes respond to light with a photochemical change, it is impossible to alter or otherwise correct the SRG once exposed. For similar reasons, ambient and stray light must be eliminated from the fabrication setup. The post-exposure chemical processing needed to reveal the SRG on the film surface likewise requires complex and expensive wet-chemistry facilities, and the depth and shape of the resulting SRG is highly sensitive to this post-exposure step.

### SUMMARY

The present disclosure provides a means to laser-print surface relief grating (SRG) structures using scanning optical polarization to photomechanically pattern the surface of a photoresponsive film. The systems of the present disclosure utilize a light source (e.g., a laser source) and a spatial light modulator (SLM) to generate a structured pattern of optical polarization that is then projected onto the surface of a moving azopolymer film (e.g., an azobenzene polymer film and/or other suitable film). The film is continuously mechanically scanned during the optical exposure, generating an SRG that is available for use immediately following exposure.

A method for generating a pattern on an azopolymer film surface is provided. The method may comprise positioning an azopolymer film onto a motorized stage of a laser optical lithography system, wherein the motorized stage is configured to move in an XY direction, setting, using a computing device comprising a processor and a memory, a desired period, amplitude, and size of surface relief grating to be printed onto a surface of the azopolymer film, and printing an image onto the surface of the azopolymer film. Printing the image may comprise generating spatially uniform linearly polarized light, using a laser source, expanding and collimating the linearly polarized light, using one or more lenses, converting the linearly polarized light to circularly polarized light, using a first quarter wave plate, converting the circularly polarized light to elliptically polarized light, using a spatial light modulator (SLM), converting the elliptically polarized light from the SLM to a final desired linearly polarized light, using a second quarter wave plate, focusing the linearly polarized light onto the surface of the azopolymer film, using a focusing objective lens, and moving the azopolymer film in relation to the final desired linearly polarized light, using the motorized stage. The azopolymer film may be positioned approximately at a focal plane of the objective lens.

According to an exemplary embodiment, the azopolymer film may comprise azobenzene chromophores coupled to a polymer.

According to an exemplary embodiment, printing the image may comprise orienting at least some of the azobenzene chromophores using the final desired linearly polarized light, causing a topographical surface pattern to form on the azopolymer film, generating a processed azopolymer film.

According to an exemplary embodiment, the azopolymer film may be positioned on a substrate.

According to an exemplary embodiment, the period may comprise a spatial period of a sinusoidal grating.

According to an exemplary embodiment, the amplitude may comprise a physical height of a sinusoidal surface relief.

According to an exemplary embodiment, the method may further comprise, using the computing device, setting a film speed at which the film is to be moved in relation to the final desired linearly polarizing light.

According to an exemplary embodiment, the first quarter wave plate may be configured to convert the linearly polarized light to the circularly polarized light at +45 degrees.

According to an exemplary embodiment, the second quarter wave plate may be configured to convert the elliptically polarized light from the SLM to the final desired linearly polarized light at −45 degrees.

According to an exemplary embodiment, a grayscale value addressed to each pixel of the SLM may be configured to generate a unique ellipticity at a spatial location of the pixel, as determined by a desired final polarization pattern to be projected onto the azopolymer film.

According to an exemplary embodiment, printing the image may comprise printing surface structures on the azopolymer film that diffract incident white light into red, green, and blue components.

According to an object of the present disclosure, a laser optical lithography system configured for generating a pattern on an azopolymer film surface is provided. The laser optical lithography system may comprise a motorized stage configured to position an azopolymer film and move in an XY direction, a computing device, comprising a processor and a memory, configured to enable a user to set a desired period, amplitude, and size of surface relief grating to be printed onto a surface of the azopolymer film, a laser source configured to generate spatially uniform linearly polarized light, one or more lenses configured to expand and collimate the linearly polarized light, a first quarter wave plate configured to convert the linearly polarized light to circularly polarized light, a spatial light modulator (SLM) configured to convert the circularly polarized light to elliptically polarized light, a second quarter wave plate configured to convert the elliptically polarized light from the SLM to a final desired linearly polarized light, and a focusing objective lens configured to focus the linearly polarized light onto the surface of the azopolymer film. The azopolymer film may be positioned approximately at a focal plane of the objective lens. The motorized stage may be configured to move the azopolymer film in relation to the final desired linearly polarized light to print an image onto the surface of the azopolymer film.

According to an exemplary embodiment, the laser optical lithography system may comprise azopolymer film.

According to an exemplary embodiment, the azopolymer film may comprise azobenzene chromophores coupled to a polymer.

According to an exemplary embodiment, the final desired linearly polarized light may be configured to orient at least some of the azobenzene chromophores, causing a topographical surface pattern to form on the azopolymer film, generating a processed azopolymer film.

According to an exemplary embodiment, the period may comprise a spatial period of a sinusoidal grating.

According to an exemplary embodiment, the amplitude may comprise a physical height of a sinusoidal surface relief.

According to an exemplary embodiment, the computing device may be configured to set a film speed at which the film is to be moved in relation to the final desired linearly polarizing light.

According to an exemplary embodiment, the first quarter wave plate may be configured to convert the linearly polarized light to the circularly polarized light at +45 degrees.

According to an exemplary embodiment, the second quarter wave plate may be configured to convert the elliptically polarized light from the SLM to the final desired linearly polarized light at −45 degrees.

According to an exemplary embodiment, the laser optical lithography system may comprise a camera configured to generate an image of the surface of the azopolymer film.

According to an exemplary embodiment, a grayscale value addressed to each pixel of the SLM may be configured to generate a unique ellipticity at a spatial location of the pixel, as determined by a desired final polarization pattern to be projected onto the azopolymer film.

According to an exemplary embodiment, the final desired linearly polarized light may be configured to print surface structures on the azopolymer film that diffract incident white light into red, green, and blue components.

Further objectives and advantages of the present disclosure will be apparent from the following detailed description of presently preferred embodiment, which is illustrated schematically in the accompanying drawings.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 illustrates an example schematic representation of a laser optical lithography system utilizing a moving photomechanically-responsive film and an optical polarization projection system utilizing a laser, spatial light modulator, and quarter-wave plates, according to an exemplary embodiment of the present disclosure.

FIG. 2A illustrates an example schematic representation of a process by which linearly polarized light induces rotation of azobenzene chromophores to orient perpendicular to optical polarization in a steady state, according to an exemplary embodiment of the present disclosure.

FIG. 2B illustrates an example schematic representation of how an example distribution of optical polarization on a film surface (also referred to as a polarization grating) causes a corresponding topographical distortion, according to an exemplary embodiment of the present disclosure.

FIG. 3A illustrates an example of a scanning electron microscope image of a cross-section of an azobenzene polymer film surface prior to illumination, according to an exemplary embodiment of the present disclosure.

FIG. 3B illustrates an example of a scanning electron microscope image of a cross-section of an azobenzene polymer film surface following a 5-second exposure, resulting in surface relief grating, according to an exemplary embodiment of the present disclosure.

FIG. 4 illustrates a schematic representation of an example mechanical translation pattern for an azobenzene polymer film while being illuminated with an optical polarization pattern, according to an exemplary embodiment of the present disclosure.

FIG. 5 illustrates a graphical representation of surface relief grating (SRG) amplitude vs translational film speed, according to an exemplary embodiment of the present disclosure.

FIG. 6 illustrates a graphical representation of a optical diffraction efficiency of red light (wavelength ˜632 nm), green light (wavelength ˜532 nm), and blue light (wavelength ˜488 nm) from SRGs replicated from azopolymer films using an inorganic hybrid polymer, according to an exemplary embodiment of the present disclosure.

FIG. 7 illustrates a flow chart of a method for laser lithographic fabrication of surface relief structures to generate a pattern on an azopolymer film surface, according to an exemplary embodiment of the present disclosure.

FIG. 8 illustrates example elements of a computing device, according to an exemplary embodiment of the present disclosure.

### DETAILED DESCRIPTION

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

An “electronic device” or a “computing device” refers to a device that comprises a processor and memory. Each device may have its own processor and/or memory, or the processor and/or memory may be shared with other devices as in a virtual machine or container arrangement. The memory may contain or receive programming instructions that, when executed by the processor, cause the electronic device to perform one or more operations according to the programming instructions.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the terms “about” and “approximately” are understood as within a range of normal tolerance in the art, for example within 2 standard deviations of the mean. “About” and “approximately” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the terms “about” and “approximately”.

Hereinafter, embodiments disclosed in this specification will be described in detail with reference to the accompanying drawings, and the same or similar elements will be given the same reference symbols regardless of drawing numbers, and redundant description thereof will be omitted. In addition, a detailed description of well-known features or functions will be ruled out in order not to unnecessarily obscure the gist of the present disclosure.

The illustrative examples described in the detailed description, drawings, and claims are not meant to be limiting. Other examples can be utilized and other changes can be made without departing from the spirit or scope of the subject matter presented herein. It will be readily understood that the aspects of the present disclosure, as generally described herein and illustrated in the figures, can be arranged, substituted, combined, separated, and designed in a wide variety of different configurations, all of which are implicitly contemplated herein.

In the following description, the terms “module” and “unit” for referring to elements are assigned and used interchangeably in consideration of convenience of explanation, and thus, the terms per se do not necessarily have different meanings or functions. Further, in describing the embodiments disclosed in the present specification, when it is determined that a detailed description of a related publicly known technology may obscure the gist of the embodiments disclosed in the present specification, the detailed description thereof will be omitted. In addition, the accompanying drawings are used to help easily understand the embodiments disclosed in this specification, the technical idea disclosed in this specification is not limited by the accompanying drawings, and it should be understood that all alterations, equivalents, and substitutes included in the spirit and scope of the present disclosure are included herein.

Although terms including ordinal numbers, that is, “first”, “second”, etc. may be used herein to describe various elements, the elements are not limited by these terms. These terms are generally only used to distinguish one element from another.

When an element is referred to as being “coupled” or “connected” to another element, the element may be directly coupled or connected to the other element. However, it should be understood that another element may be present therebetween. In contrast, when an element is referred to as being “directly coupled” or “directly connected” to another element, it should be understood that there are no other elements therebetween.

A singular expression includes the plural form unless the context clearly dictates otherwise.

In the present specification, it should be understood that a term such as “include” or “have” is intended to designate that the features, numbers, steps, operations, elements, parts, or combinations thereof described in the specification are present, and does not preclude the possibility of addition or presence of one or more other features, numbers, steps, operations, elements, parts, or combinations thereof.

The present disclosure generally describes systems and methods for using a laser optical lithography system to laser-print surface relief gratings (SRGs), in real-time, on a moving azobenzene polymer film, with the SRG available for use immediately following exposure. The laser optical lithography system and method may be configured to use a spatial light modulator (SLM) as an optical polarization projector and a continuously moving photomechanically-responsive film for the fabrication of SRGs. By utilizing the polarization of the writing beams to mechanically redistribute the film mass from a flat surface to a topographical surface relief, many of the limitations of currently employed LI and OD processes are eliminated.

Photomechanically-responsive films consist of an azobenzene molecule coupled to a polymer host. When such films absorb linearly polarized light, the azobenzene molecule physically rotates until its molecular axis is perpendicular to the optical polarization, at which point it ceases movement. Because the azobenzene is coupled to its polymer host, the rotational movement exerts a torque on the polymer, ultimately distorting the surface of the polymer film. Projecting a spatial distribution of linearly polarized light on the surface of the azobenzene polymer film, for example one in which the orientation periodically rotates, then results in a distortion of the film surface topography with the same periodicity.

Because the surface distortion process arises from a light-driven mechanical change of the material, the SRG appears immediately in response to light, and requires no post-exposure chemical processing. Likewise, the photomechanical response of the film allows a previously-written SRG to be optically erased or altered by exposure to the appropriate projected polarization pattern. Such films are also far less susceptible to environmental disturbances such as mechanical and acoustic vibration.

SRGs on azobenzene polymer films are typically fabricated using LI techniques, with additional optical components such as quarter-waveplates inserted into the beam path to generate the polarization needed to drive the surface distortion. As is typical for LI processes, the optomechanical arrangement may expose the film with only a single polarization pattern of a fixed periodicity. Current data indicates that SRGs may be formed in real-time on azobenzene polymer films with exposures of 0-5 seconds. These SRGs are available for replication immediately after exposure and require no additional processing. The typical area of a single SLM exposure is of order 0.03 mm². In this process, a single SRG with a fixed amplitude, period, and orientation may be formed due to a single, timed exposure on an azobenzene polymer film that is fixed in a single location.

By utilizing continuous movement of the azobenzene film while exposed to the SLM-generated polarization pattern, the systems and methods of the present disclosure may increase the SRG area on the film from 0.03 mm² to at least 100 mm² by executing a raster-scanned movement. The SRG amplitude, period, and orientation may all be continuously varied through user-defined control of the film speed and the projected polarization pattern as set by the user via SLM programming.

Of particular importance and value is that a translation speed of the film imbues the present systems and methods with a new control parameter for SRG production because the surface distortion is driven by the unique photomechanical response of the film. In addition, the SLM allows the user to spatially define the optical polarization on the film surface, which may be used as an additional control on the SRG amplitude. Therefore, the present systems and methods may be configured to enable SRG amplitude to be spatially defined on the film surface purely through control of the local optical polarization, with no need to change the illuminating intensity. The features described above are not possible with currently employed LI and OD processes that use photochemical films and are likewise not possible with SLM-based systems which utilize photomechanical azobenzene polymer films in a fixed (non-moving) configuration.

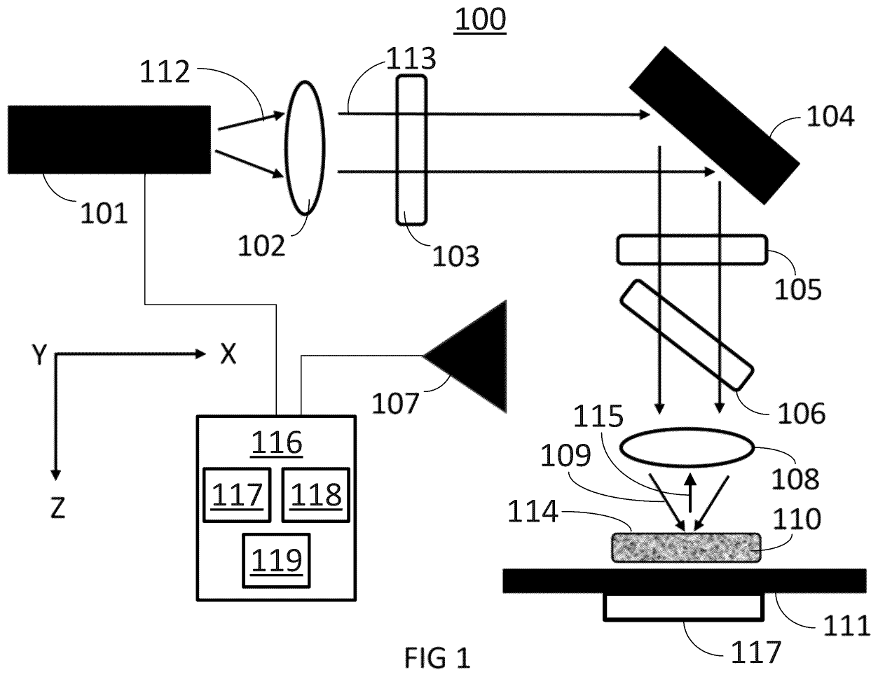

Referring now to FIG. 1, a laser optical lithography system 100 utilizing a moving photomechanically-responsive film 110 and an optical polarization projection system utilizing a laser 101, a spatial light modulator (SLM) 104 configured to generate a polarization pattern, and one or more quarter-wave plates 103, 105 is illustratively depicted, in accordance with an exemplary embodiment of the present disclosure.

According to an exemplary embodiment, the laser optical lithography system 100 may be configured such that the laser source 101 may be configured to emit spatially uniform linearly polarized light 112. The spatially uniform linearly polarized light 112 may be configured to be expanded and collimated by a lens arrangement comprising one or more lenses 102. The expanded and collimated light 113 may then passes through an optical quarter-wave plate 103 oriented at +45 degrees, reflect from the spatial light modulator 104, and pass through another quarter-wave plate 105 oriented at −45 degrees.

According to an exemplary embodiment, the two quarter-wave plates 103, 105 and SLM 104 convert the spatially uniform linear polarization of the light into a spatially patterned distribution of linear optical polarization, as determined by the optical retardation of each pixel of the SLM 104. The light 113 then passes through a dichroic mirror 106 and a focusing objective lens 108, forming a demagnified beam 109.

The demagnified beam 109 may be focused onto a surface 114 of a polarization-sensitive azobenzene polymer film 110, also referred to as a laser-printing film. The laser-printing film 110 may be mounted on a motorized stage 111 configured to be moved in the XY direction via one or more motors 117. According to an exemplary embodiment, the azopolymer film 110 may be positioned approximately at a focal plane of the objective lens 108. The motorized stage 111 may be configured to cause the laser-printing film 110 to undergo continuous movement in the XY plane while being illuminated by the demagnified beam 109. This effectively prints an SRG, in real-time (i.e., as the demagnified beam 109 projects onto the laser-printing film 110) on the film surface 114 as it moves under the demagnified beam 109.

According to an exemplary embodiment, the dichroic mirror 106 and the camera 107 may be configured to collect light 115 reflected from the film surface during the writing process and facilitate real-time observation of the writing process.

According to an exemplary embodiment, the laser optical lithography system 100 may comprise one or more computing devices 116. According to an exemplary embodiment, the one or more computing devices may comprise one or more processors 117, memories 118, and/or user interfaces (e.g. graphical user interfaces, displays, keyboards, mice, touchscreens, etc.) 119. According to an exemplary embodiment, the memory 118 may be configured to store programming instructions that, when executed by the processor 117, are configured to cause the processor 117 to perform one or more tasks such as, e.g., causing the laser source to emit the spatially uniform linearly polarized light 112, causing the camera 107 to collect light 115 reflected from the film surface during the writing process and/or facilitate real-time observation of the writing process, and/or other suitable tasks. According to an exemplary embodiment, the one or more computing devices 116 may be coupled to the laser source 101 and/or the camera 107.

The process by which optical polarization drives SRG growth is based on the molecular-scale physical movement of the azobenzene components and, as such, is different from the photochemical processes currently employed by optical lithography. This fundamental difference of the present disclosure offers significant advantages over existing scanning optical lithographic methods. Also note that the molecular-scale movement is not related to the continuous XY movement of the azobenzene polymer film 110 during illumination in the laser-writing process. The molecular-scale movement that ultimately drives the SRG formation occurs regardless of the film's 110 bulk motion.

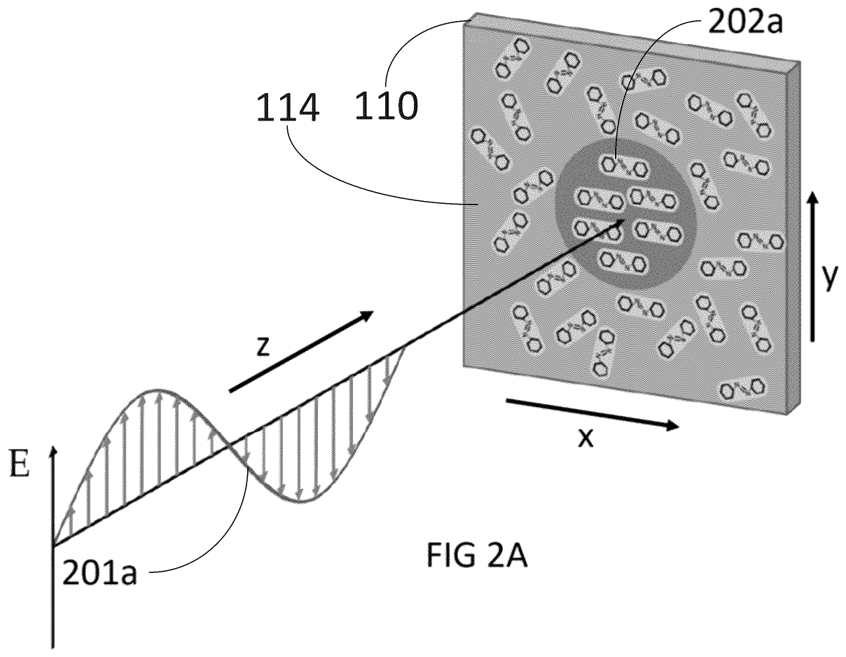

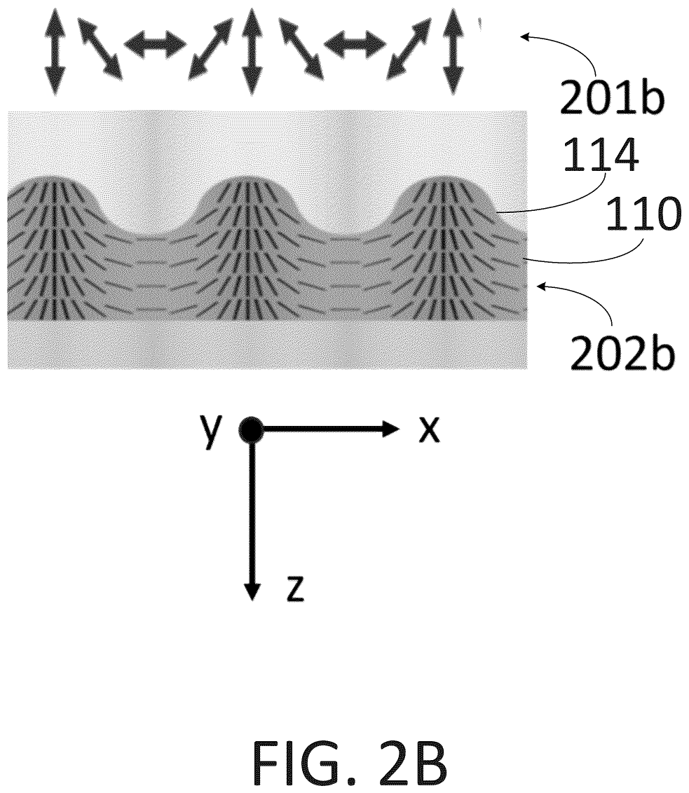

According to an exemplary embodiment, the light-induced molecular scale movement (also referred to as the photomechanical response of azopolymers) originates in the Weigert effect, illustrated in FIG. 2A.

As shown in FIG. 2A, linearly polarized light 201a, incident on a collection of initially randomly oriented azobenzene molecules, drives rotational motion of the azobenzene via cyclic cis-trans isomerization. This motion continues until the linear trans-conformation is trapped perpendicular to the optical polarization, thereby resulting in azobenzene chromophores 202a being rotates to orient perpendicular to the optical polarization in steady state. According to an exemplary embodiment, printing the image onto the azopolymer film may comprise orienting at least some of the azobenzene chromophores, which causes a topographical surface pattern to form on the azopolymer film, generating a processed azopolymer film.

By coupling the azobenzene to a polymer host, the molecular orientation may be transmitted to the polymer 110, effectively causing a bulk mass movement that, if repeated over macroscopic length scales in the order of micrometers, will deform the surface of the film into an SRG. As shown in FIG. 2B, an optical polarization on a film surface 201b (also referred to as a polarization grating) may be configured to cause a corresponding topographical distortion 202b.

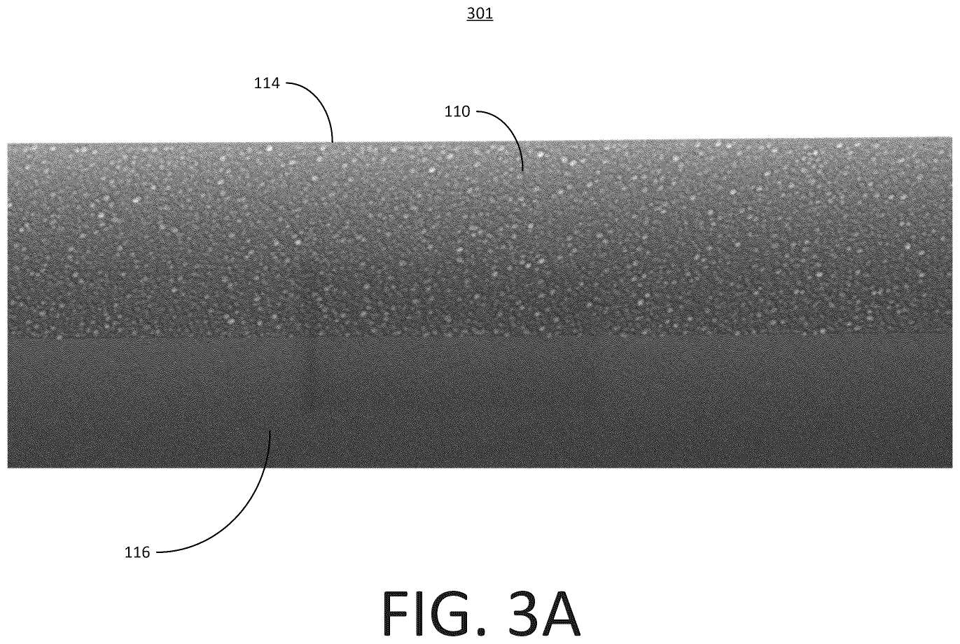

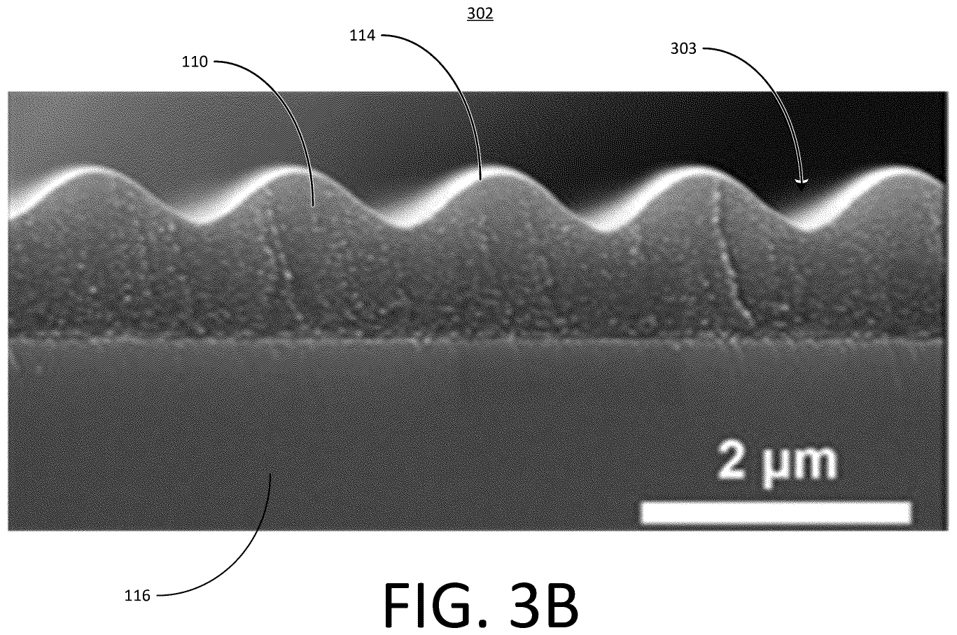

Scanning electron microscope (SEM) images, as shown in FIGS. 3A-3B, show a typical response of azopolymer film (e.g., an azopolymer writing film) 110 to unpolarized illumination (SEM image 301), and an azopolymer film 110 following a 5-second exposure, resulting in polarizing surface relief grating 303 (SEM image 302).

According to exemplary embodiments, surface relief structures (e.g., surface relief grating 303) on azopolymer films 100 may be generated with lasers of wavelengths of approximately 400 nm-550 nm and exposure times of less than 5 minutes. It is noted, however, that other wavelengths, intensities, and/or exposure times may be implemented, while maintaining the spirit and functionality of the present disclosure. Beneficially, the surface structures may grow in response to light, may require no further processing, and/or may be stable in ambient conditions.

Because of their photo-orientable characteristics, azopolymers 110 have attracted considerable interest. Initial research focused on the development of covalently coupled systems, requiring complex synthetic steps. However, the emergence of supramolecular azopolymer materials has resulted in a self-assembled, inexpensive, and highly modular material for surface microstructures. Such systems exploit weak electrostatic coupling between the azobenzene and polymer, usually in the form of hydrogen bonding. A particularly versatile supramolecular system is based on 4-hydroxy-40-dimethylaminoazobenzene and poly(4-vinylpyridine) (denoted by OH-DMA-P4VP) (Structure 1).

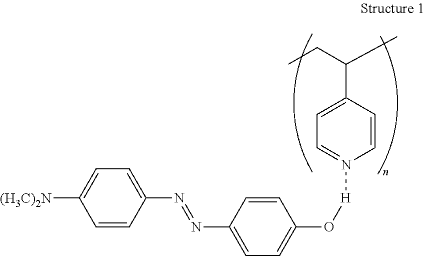

Thin films spincast from OH-DMA-P4VP in solution exhibit excellent optical clarity and homogeneity, and complexations up to 1:1 (1 chromophore per 1 polymer repeat unit) are possible without aggregation. It is noted that, while OH-DMA-P4VP is an azopolymer system that may be used as a laser-printing film according to an present disclosure, it is described as a representative example, and other suitable films (e.g., other varieties of supramolecular azopolymer, etc.) may be used and/or incorporated while maintaining the spirit and functionality of the present disclosure.

According to an exemplary embodiment, a typical film 110 thickness may be approximately 2 microns and may be spincast on circular glass substrates 116 of diameter 2.54 cm. It is noted, however, that other suitable film thicknesses, substrate materials, and substrate dimensions and/or areas may be used while maintaining the spirit and functionality of the present disclosure.

Current methods employed to generate optical polarization on azobenzene polymer film surfaces needed for writing an SRG is laser interferometry (LI), in which two laser beams are overlapped on the surface of the film. This technique is severely limited in practice because changing the period and/or orientation of the SRG requires a complete optomechanical reconfiguration of the setup. The setup for LI is likewise highly susceptible to mechanical vibration.

The systems and methods of the present disclosure avoid these limitations by employing an SLM 104 as a polarization projection device. Specifically, the laser-printing film polymer film (e.g., OH-DMA-P4VP and/or other suitable file) may be coupled with an optical apparatus, as shown in FIG. 1. The combination of laser 101, optical waveplates 105 115, SLM 104, and objective lens 108 forms an optical polarization projector, which projects an appropriate optical polarization onto the film surface 114. The film 110 may be mounted on a computer-controlled XY or rotational stage 111 to provide continuous movement of the film 110 during exposure. The dichroic mirror 106 and camera 107 provide for real-time observation of the SRG fabrication process.

According to an exemplary embodiment, a central feature of the optical system 100 setup is an optical rotator (OR) arrangement, consisting of a λ/4-SLM-λ/4 combination, where λ/4 is a quarter-wave optical retarder. This rotates the plane of polarization of an incident linearly polarized laser beam by dθ, where dθ is set by a programmable optical retardation as determined by a gray-scale value addressed to the SLM 104.

According to an exemplary embodiment, addressing the SLM 104 with a linear sawtooth pattern of grayscale values from approximately 0-255 may generate a spatially periodic orientation of linearly polarized light which rotates its orientation over at least 2π radians. This linearly polarized light may then be de-magnified and imaged onto the film surface using a microscope objective.

According to an exemplary embodiment, the SLM 104 may comprise a liquid crystal on silicon device. According to an exemplary embodiment, the SLM 104 may comprise approximately 1920×1152 pixels on an active area of approximately 17.7 mm×10.6 mm. It is noted, however, that this configuration of the SLM 104 is presented as an example and that other SLM 104 material types, pixel configurations/quantities, and/or dimensions may be incorporated, while maintaining the spirit and functionality of the present disclosure. According to an exemplary embodiment, the light from the SLM 104 may be imaged onto the film surface using a microscope objective.

According to an exemplary embodiment, the laser source 101 may comprise a 488 nm diode-pumped solid-state laser, which efficiently pumps the cis-trans isomerization of the azobenzene chromophore. It is noted, however, that other suitable laser sources 101 may be incorporated, while maintaining the spirit and functionality of the present disclosure.

For the example system 100 shown in FIG. 1, the projected image of the SLM 104 onto the film surface 114 may be of area 130 μm×80 μm. It is noted, however, that other suitable SLMs 104, laser 101 wavelengths, and objective lenses 108 may be incorporated while maintaining the spirit and functionality of the present disclosure.

According to an exemplary embodiment, this system 100 arrangement may be configured to map a gray-scale function addressed to the SLM 104 to a corresponding spatial orientational arrangement of linearly polarized light, which then generates a surface relief structure on an azopolymer film 110. An advantage is that the SLM 104 is spatially addressable, thus enabling the optical inscription of surface microstructures of, in principle, any geometrical configuration, limited only by the pixel size and overall optical resolution of the system 100.

According to an exemplary embodiment, to achieve control over the SRG amplitude and to laser-print larger area structures needed for applications, the azobenzene polymer film 110 may be mounted on a computer-controlled XY or rotational motor stage 111. The film 110 may then be continuously translated while being illuminated with the spatial polarization distribution provided by the SLM 104. This effectively results in a scanning spot of 130 μm×80 μm (or other suitable dimension, as the materials may be and the system 100 may be configured to generate) using the above parameters, as an example. It is noted, however, that the system 100 is not limited to this scanning spot size, and many other sizes are possible depending on the application.

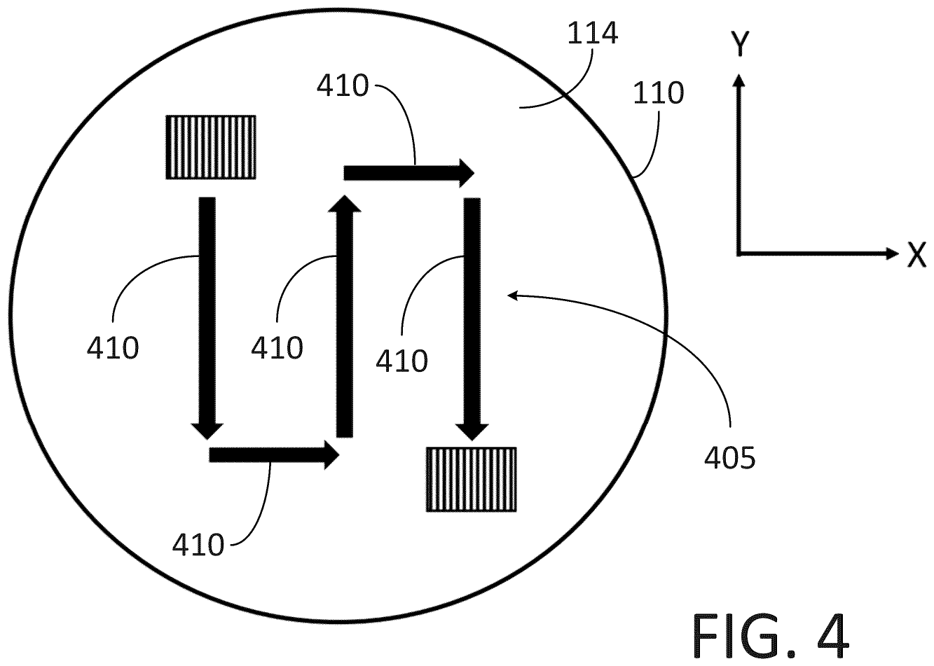

According to an exemplary embodiment, for an example linear SRG, a scanning pattern 405 is shown, e.g., in FIG. 4. For example, as the film 110 reaches the end of a particular column of laser-printing, the film 110 may be translated laterally by an integer multiple of the SRG period (for example for periodic SRG) and the scanning process repeated. In this fashion, rectangular SRGs may be fabricated. According to an exemplary embodiment, rectangular SRGs may be fabricated with areas up to 25 mm². However, this area is representative, and is only limited by the physical size of the film and the translation range of the XY motors 111. According to an exemplary embodiment, circular SRGs are also possible by mounting the film in a rotating motorized stage. It is noted, however, that other shaped SRGs are also possible, while maintaining the spirit and functionality of the present disclosure.

### Example Functionality:

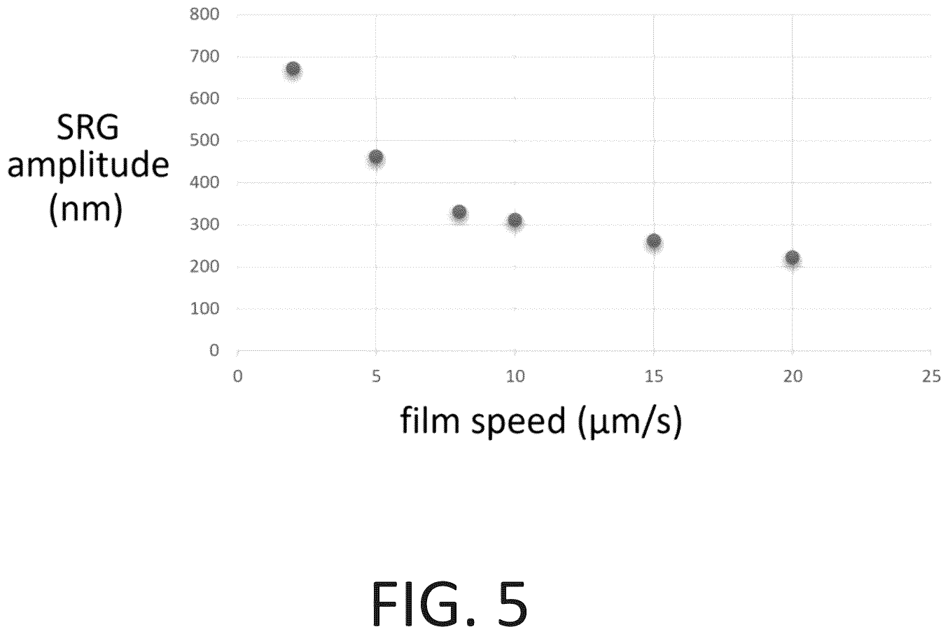

According to an example demonstration of the current disclosure, consider the fabrication of a surface relief grating with a sinusoidal profile. The SLM 104 may be addressed with a sawtooth pattern of 84 cycles which, when projected onto a film 110 surface 114 with a 40× objective, results in a linear polarization period of 2.0 μm over an exposure area of 130 μm×80 μm. The film 110 may then be translated by the XY motors at constant speed and optical power during the exposure process, following the pattern shown, e.g., in FIG. 4. The area of each SRG in this example demonstration is 0.25 mm×1.00 mm. The demonstration was repeated at speeds ranging from 2 μm/s to 20 μm/s. After each SRG printing process, the film 110 was removed and characterized by atomic force microscopy (AFM). The summary results of this example are shown in FIG. 5, where it is seen that the systems 100 and methods 700 of the present disclosure may be configured to enable laser-printing in real-time with SRGs ranging from 220 nm to 670 nm of surface modulation depth. These results are representational, and were obtained using a fixed optical power of 10 mW at the film 110 surface 114 and over translation film speeds of 2 μm/s to 20 μm/s. It is noted, however, that other amplitudes and periods are possible by changing the optical power, film speed, and period addressed to the SLM 104.

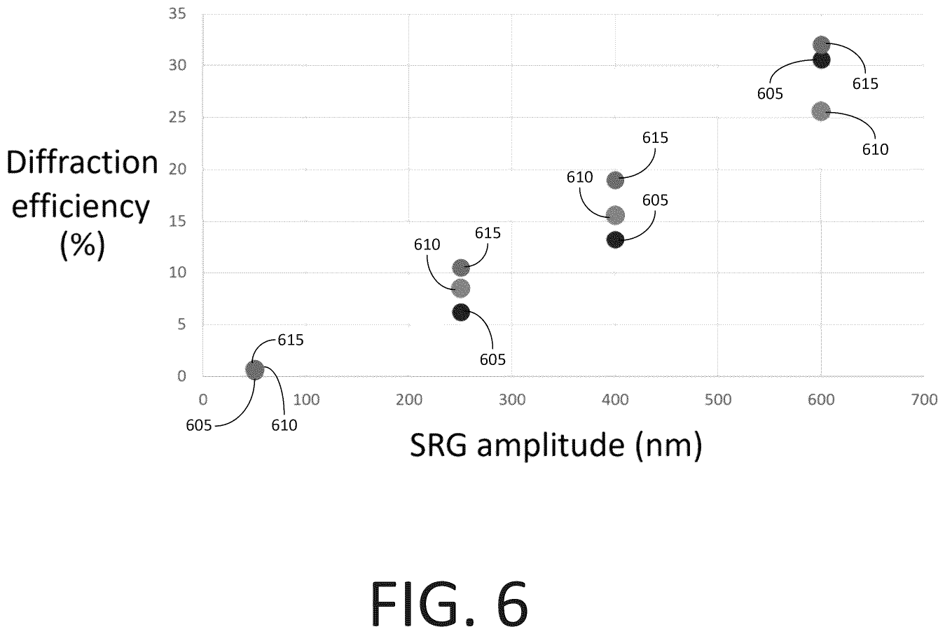

According to an exemplary embodiment, selected speeds from the above-described laser-writing process may be extended to create SRG of an approximate surface area of 5 mm×5 mm. The resulting large-area SRG on the azopolymer film may be immediately replicated using nanoimprint lithography using optically transparent inorganic hybrid polymer material, demonstrating that the present systems and methods, when used with an azopolymer thin film, may be configured to fabricate master SRG gratings suitable for volume reproduction. According to an exemplary embodiment, the inorganic-organic hybrid polymer may be initially a liquid and may be configured to be hardened with the application of ultraviolet (UV) light to exhibit glass-like properties. To characterize the diffraction performance of these replicated gratings, their diffraction efficiency was measured at 632 nm 605, 532 nm 610, and 488 nm 615, with the results shown in FIG. 6. The measured diffraction efficiencies all agree with theoretical predictions.

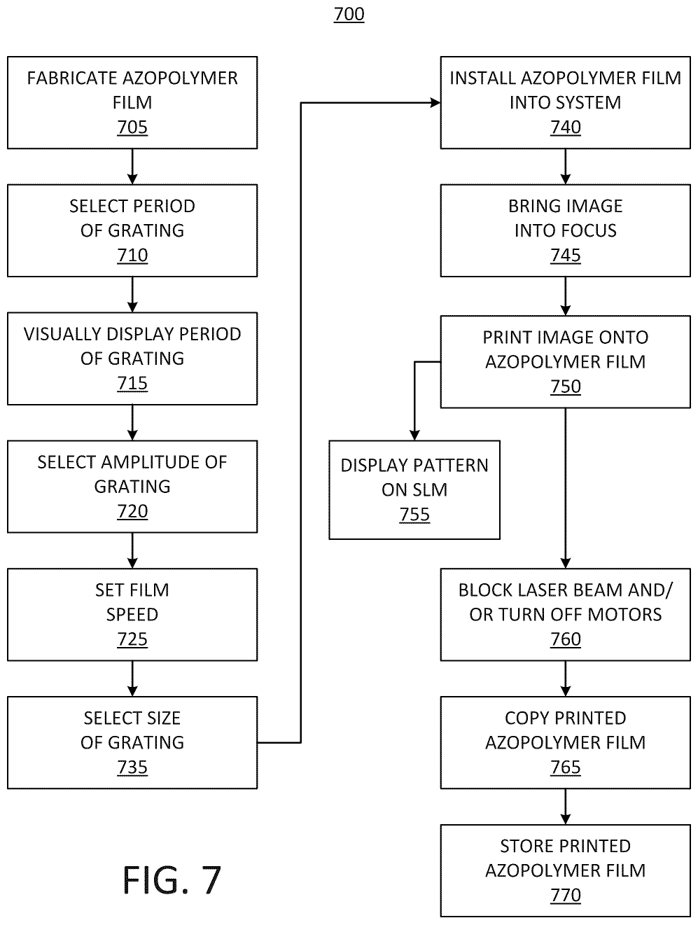

Referring now to FIG. 7, a method 700 for laser lithographic fabrication of surface relief structures to generate a pattern on an azopolymer film surface, in accordance with an exemplary embodiment of the present disclosure.

At 705, an azopolymer film (i.e., an azopolymer writing film, a “blank” film, printing paper, etc.) may be fabricated. According to an exemplary embodiment, the azopolymer film may be fabricated in a desired size and/or geometry. The azopolymer film may be positioned on a substrate (e.g., a glass substrate and/or other suitable substrate). The substrate may be of a similar size to the azopolymer film. According to an exemplary embodiment, a typical azopolymer film may be approximately 25.4 mm or 50.8 mm in diameter on a circular glass substrate of same diameter. It is noted, however, that other sized azopolymer films and/or substrates may be incorporated while maintaining the spirit and functionality of the present disclosure.

At 710, a period of the grating to be printed may be selected, using, e.g., a graphical user interface. According to an exemplary embodiment, a period, Xₘₐₓ, is a spatial period of a sinusoidal grating to be written on the film. According to an exemplary embodiment, once the period, Xₘₐₓ, is selected, it may be visually displayed, at 715, on a graphical user interface for a user to see. As an example, a user input of Xₘₐₓ=30 pixels may result in a physical period of 2.0 microns on a film surface.

At 720, an amplitude of the grating to be printed may be selected, using, e.g., a graphical user interface. According to an exemplary embodiment, the amplitude, A, is the physical height of the sinusoidal surface relief to be printed on the film surface. According to an exemplary embodiment, this may be controlled by a speed of one or more motors configured to move the film under the laser beam. According to an exemplary, the amplitude, A, may be taken as input, and the computing system of the system may, at 725, set an appropriate film speed, based on the amplitude, A, at which the film is to be moved in relation to the linearly polarizing light, as shown, e.g., in FIG. 5.

At 730, a size of the grating on the azopolymer film may be selected. The size of the grating is the physical size of the image desired on the film surface. According to an exemplary embodiment, the size of the grating may be taken as input and the computing device, at 735, may calculate one or more raster steps 410, as shown, e.g., in FIG. 4. For example, a user input requesting a 5 mm×5 mm grating on the azopolymer film would require 38 scans in the Y-direction, with each scan moving a distance of 5 mm in the Y-direction, and the X-step distance would be 130 microns.

At 740, the azopolymer film may be installed into the system. According to an exemplary embodiment, the azopolymer film may be physically installed onto an XY motor stage (e.g., stage 111 of FIG. 1). Once installed, the image of the film surface may be visible using a camera (e.g., camera 107 of FIG. 1). At 745, the image may be brought into focus on the azopolymer film surface. According to an exemplary embodiment, a Z-direction position of the XY stage may be adjusted to bring the image into focus.

At 750, the image may be printed onto the azopolymer film. According to an exemplary embodiment, during the printing process, the computing device may turn on the laser source, generating the laser beam which contacts the azopolymer film, and may communicate with the one or more motors of the stage to move the azopolymer film in relation to the laser beam, generating the image on the azopolymer film. According to an exemplary embodiment, during the printing process, spatially uniform linearly polarized light may be generated using a laser source, the linearly polarized light may be expanded and collimated using one or more lenses, the linearly polarized light may be rotated +45 degrees using a first quarter-wave plate, a polarization pattern in the linearly polarized light may be generated using the SLM, the linearly polarized light may be converted to circularly polarized light using a first quarter wave plate at +45 degrees, the circularly polarized light may be converted to elliptically polarized light using the SLM, the elliptically polarized light may be converted from the SLM to a final desired linearly polarized light using a second quarter wave plate at −45 degrees, the linearly polarized light may be focused onto the surface of the azopolymer film using a focusing objective lens, and the azopolymer film may be moved in relation to the linearly polarized light, using a motorized stage configured to move in an XY direction. According to an exemplary embodiment, the laser optical lithography system may be aligned to enable the polarization pattern, generate by the SLM, to be projected onto a surface of the azopolymer film. According to an exemplary embodiment, a grayscale value addressed to each pixel of the SLM may be configured to generate a unique ellipticity at a spatial location of the pixel, as determined by a desired final polarization pattern to be projected onto the azopolymer film.

According to an exemplary embodiment, during the printing of the image onto the azopolymer film, the user-input pattern, at 755, may be displayed on the SLM. According to an exemplary embodiment, the physical surface grating may be visible, in real-time, via the camera, as the image is being printed.

According to an exemplary embodiment, the system may be configured to print surface structures that diffract incident white light into red (R), green (G), and blue (B) components, all of which may then propagate as diffraction modes along a common direction, ⊖. According to an exemplary embodiment, a viewer may perceive the summation of these component colors, seeing a single RGB color that can be precisely specified by the respective R, G, and B values.

For example, consider that a 130 μm×80 μm scanning area produced by the SLM may be subdivided into 3 regions, each with a unique spatial period, dᵣ, d_{g}, and d_{b}, and area, Aᵣ, A_{g}, and A_{b}. This subdivision may be enabled via programming instructions that, when executed, are configured to cause a processor to operate the SLM. Defining the period relationship among the 3 regions as λᵣ=λ_{g}/d_{g}=λ_{b}/d_{b} (where λᵣ=0.633 μm, λ_{g}=0.532 μm, and λ_{b}=0.488 μm) produces a first order diffracted mode in which red, green, and blue light propagate at a common angle as specified by the diffraction relationship λ=d sin ⊖. As a specific example, if the periods are defined as dᵣ=2.59 μm, d_{g}=2.18 μm, and d_{b}=2.0 μm, then red, green, and blue light will all diffract along the common angle of 14.1 deg with respect to the film surface normal. The proportional intensity of each color may then be determined by the areas Aᵣ, A_{g}, and A_{b}. These are the physical areas of the SLM device, wherein each area is written with its respective periodicity (i.e. dᵣ=2.59 μm, d_{g}=2.18 μm, or d_{b}=2.0 μm).

At 760, following the printing of the image on the azopolymer film, the laser beam may be blocked (e.g., via a shutter, via turning off the laser source, and/or other suitable means) and/or the motors are stopped. The printed (or processed) azopolymer film may then be removed from the system. The printed azopolymer film may then be immediately used for diffraction experiments.

At 765, the printed azopolymer film may be copied. According to an exemplary embodiment, the printed azopolymer film may be copied onto a transparent material (such as, e.g., azopolymer films using an inorganic hybrid polymer) which will then exhibit diffraction characteristics as shown, e.g., in FIG. 6. The original printed azopolymer film may then, at 770, be stored as a master “print” for future replication.

According to an exemplary embodiment, the real-time printing of the SRG in the manners described above offer several key benefits over currently employed technologies. For example, the SRG amplitude may be precisely controlled by translational speed. In the example demonstrated here, amplitudes from 220-670 nm may be achieved with speeds of 2 to 20 μm/s, respectively. Such speeds are available with the motors employed and are not to be construed as limitations. Additionally, because the SRG process originates in the relatively slow movement of polymer mass, the continuous translation of the film during the writing process provides a highly beneficial averaging effect, producing SRG amplitudes of highly uniform amplitude and period. For similar reasons, the systems and methods of the present disclosure are therefore immune to high-frequency vibrations and other mechanical disturbances that severely impact currently employed optical lithographic techniques that use photochemical processes.

Furthermore, the user-definable optical polarization distribution may itself be used to spatially address the SRG amplitude. Therefore, while the film speed may be used to control amplitude for the entire 130 μm×80 μm focused exposure area, it may not be used to vary the amplitude within that area. However, the optical polarization pattern may be spatially modified within that area to provide spatially-addressed amplitude control of the SRG. As another advantage, the period and orientation of the SRG may be continuously varied during the laser-printing process via user-programming of the pattern addressed to the SLM. This is particularly valuable in the fabrication of SRG with continuously varying period (i.e., chirped gratings), which is an exceptionally difficult fabrication process for all of the currently employed optical lithographic fabrication technologies.

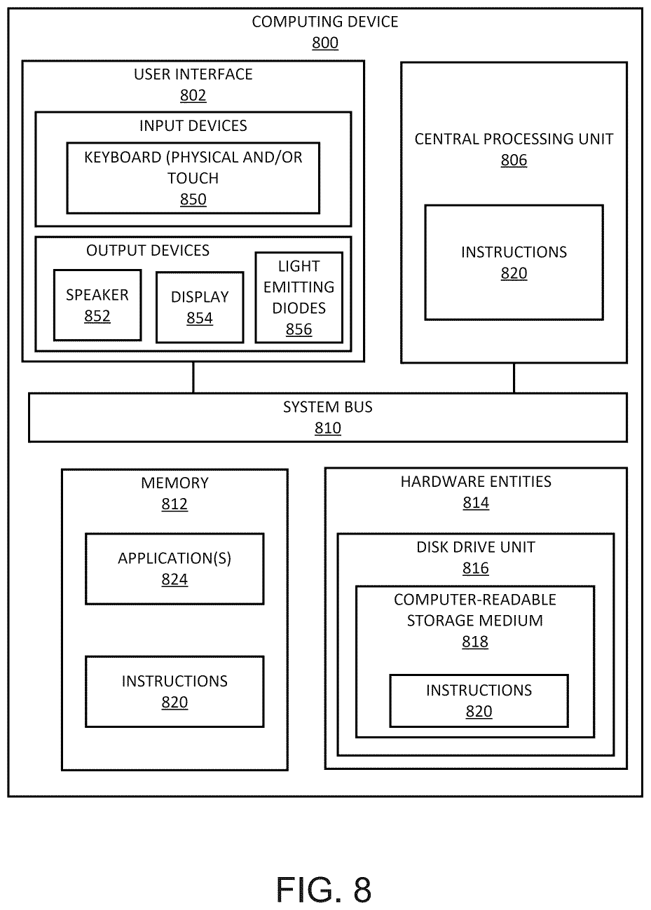

Referring now to FIG. 8, an illustration of an example architecture for a computing device 800 is provided. According to an exemplary embodiment, one or more functions of the present disclosure may be implemented by a computing device such as, e.g., computing device 800 or a computing device similar to computing device 800. Computing device 800 may be a quantum computer, a classical computer, and/or have one or more components configured to perform one or more quantum and/or classical computing functions. Computing device 116 may be an example of computing device 800 and/or may comprise one or more components of computing device 800.

The hardware architecture of FIG. 8 represents one example implementation of a representative computing device configured to implement at least a portion of the systems/devices (e.g., system 100) and method(s)/control logic(s) (e.g., method 700) described herein.

Some or all components of the computing device 800 may be implemented as hardware, software, and/or a combination of hardware and software. The hardware may comprise, but is not limited to, one or more electronic circuits. The electronic circuits may comprise, but are not limited to, passive components (e.g., resistors and capacitors) and/or active components (e.g., amplifiers and/or microprocessors). The passive and/or active components may be adapted to, arranged to, and/or programmed to perform one or more of the methodologies, procedures, or functions described herein.

As shown in FIG. 8, the computing device 800 may comprise a user interface 802 (e.g., a graphical user interface), a Central Processing Unit (“CPU”) 806, a system bus 810, a memory 812 connected to and accessible by other portions of computing device 800 through system bus 810, and hardware entities 814 connected to system bus 810. The user interface may comprise input devices and output devices, which may be configured to facilitate user-software interactions for controlling operations of the computing device 800. The input devices may comprise, but are not limited to, a physical and/or touch keyboard 840. The input devices may be connected to the computing device 800 via a wired or wireless connection (e.g., a Bluetooth® connection). The output devices may comprise, but are not limited to, a speaker 842, a display 844, and/or light emitting diodes 846.

At least some of the hardware entities 814 may be configured to perform actions involving access to and use of memory 812, which may be a Random Access Memory (RAM), a disk driver and/or a Compact Disc Read Only Memory (CD-ROM), among other suitable memory types. Hardware entities 814 may comprise a disk drive unit 816 comprising a computer-readable storage medium 818 on which may be stored one or more sets of instructions 820 (e.g., programming instructions such as, but not limited to, software code) configured to implement one or more of the methodologies, procedures, or functions described herein. The instructions 820 may also reside, completely or at least partially, within the memory 812 and/or within the CPU 806 during execution thereof by the computing device 800.

The memory 812 and the CPU 806 may also constitute machine-readable media. The term “machine-readable media”, as used here, refers to a single medium or multiple media (e.g., a centralized or distributed database, and/or associated caches and servers) that store the one or more sets of instructions 820. The term “machine-readable media”, as used here, also refers to any medium that is capable of storing, encoding, or carrying a set of instructions 820 for execution by the computing device 800 and that cause the computing device 800 to perform any one or more of the methodologies of the present disclosure.

What has been described above includes examples of the subject disclosure. It is, of course, not possible to describe every conceivable combination of components or methodologies for purposes of describing the subject matter, but it is to be appreciated that many further combinations and permutations of the subject disclosure are possible. Accordingly, the claimed subject matter is intended to embrace all such alterations, modifications, and variations that fall within the spirit and scope of the appended claims.

In particular and in regard to the various functions performed by the above described components, devices, systems and the like, the terms (including a reference to a “means”) used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the claimed subject matter.

The aforementioned systems and components have been described with respect to interaction between several components. It can be appreciated that such systems and components can include those components or specified sub-components, some of the specified components or sub-components, and/or additional components, and according to various permutations and combinations of the foregoing. Sub-components can also be implemented as components communicatively coupled to other components rather than included within parent components (hierarchical). Additionally, it should be noted that one or more components may be combined into a single component providing aggregate functionality or divided into several separate sub-components. Any components described herein may also interact with one or more other components not specifically described herein.

In addition, while a particular feature of the subject innovation may have been disclosed with respect to only one of several implementations, such feature may be combined with one or more other features of the other implementations as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

Thus, the embodiments and examples set forth herein were presented in order to best explain various selected embodiments of the present disclosure and its particular application and to thereby enable those skilled in the art to make and use embodiments of the disclosure. However, those skilled in the art will recognize that the foregoing description and examples have been presented for the purposes of illustration and example only. The description as set forth is not intended to be exhaustive or to limit the embodiments of the disclosure to the precise form disclosed.

What is claimed is:

1. A method for generating a pattern on an azopolymer film surface, comprising:
positioning an azopolymer film onto a motorized stage of a laser optical lithography system, wherein the motorized stage is configured to move in an XY direction;
setting, using a computing device comprising a processor and a memory, a desired period, amplitude, and size of surface relief grating to be printed onto a surface of the azopolymer film;
printing an image onto the surface of the azopolymer film, wherein the printing the image comprises:
generating spatially uniform linearly polarized light, using a laser source;
expanding and collimating the linearly polarized light, using one or more lenses;
converting the linearly polarized light to circularly polarized light, using a first quarter wave plate;
converting the circularly polarized light to elliptically polarized light, using a spatial light modulator (SLM);
converting the elliptically polarized light from the SLM to a final desired linearly polarized light, using a second quarter wave plate;
focusing the linearly polarized light onto the surface of the azopolymer film, using a focusing objective lens,
wherein the azopolymer film is positioned approximately at a focal plane of the objective lens; and
moving the azopolymer film in relation to the final desired linearly polarized light, using the motorized stage.

2. The method of claim 1, wherein the azopolymer film comprises azobenzene chromophores coupled to a polymer.

3. The method of claim 2, wherein printing the image comprises orienting at least some of the azobenzene chromophores using the final desired linearly polarized light, causing a topographical surface pattern to form on the azopolymer film, generating a processed azopolymer film.

4. The method of claim 1, wherein the azopolymer film is positioned on a substrate.

5. The method of claim 1, wherein the period is a spatial period of a sinusoidal grating.

6. The method of claim 5, wherein the amplitude is a physical height of a sinusoidal surface relief.

7. The method of claim 1, further comprising, using the computing device, setting a film speed at which the film is to be moved in relation to the final desired linearly polarizing light.

8. The method of claim 1, wherein the first quarter wave plate is configured to convert the linearly polarized light to the circularly polarized light at +45 degrees.

9. The method of claim 8, wherein the second quarter wave plate is configured to convert the elliptically polarized light from the SLM to the final desired linearly polarized light at −45 degrees.

10. The method of claim 1, wherein a grayscale value addressed to each pixel of the SLM is configured to generate a unique ellipticity at a spatial location of the pixel, as determined by a desired final polarization pattern to be projected onto the azopolymer film.

11. The method of claim 1, wherein printing the image comprises printing surface structures on the azopolymer film that diffract incident white light into red, green, and blue components.

12. A laser optical lithography system configured for generating a pattern on an azopolymer film surface, comprising:
a motorized stage configured to:
position an azopolymer film; and
move in an XY direction;
a computing device, comprising a processor and a memory, configured to enable a user to set a desired period, amplitude, and size of surface relief grating to be printed onto a surface of the azopolymer film;
a laser source configured to generate spatially uniform linearly polarized light;
one or more lenses configured to expand and collimate the linearly polarized light;
a first quarter wave plate configured to convert the linearly polarized light to circularly polarized light;
a spatial light modulator (SLM) configured to convert the circularly polarized light to elliptically polarized light;
a second quarter wave plate configured to convert the elliptically polarized light from the SLM to a final desired linearly polarized light; and
a focusing objective lens configured to focus the linearly polarized light onto the surface of the azopolymer film,
wherein:
the azopolymer film is positioned approximately at a focal plane of the objective lens, and
the motorized stage is configured to move the azopolymer film in relation to the final desired linearly polarized light to print an image onto the surface of the azopolymer film.

13. The laser optical lithography system of claim 12, further comprising the azopolymer film, wherein the azopolymer film comprises azobenzene chromophores coupled to a polymer.

14. The laser optical lithography system of claim 13, wherein the final desired linearly polarized light is configured to orient at least some of the azobenzene chromophores, causing a topographical surface pattern to form on the azopolymer film, generating a processed azopolymer film.

15. The laser optical lithography system of claim 12, wherein:
the period is a spatial period of a sinusoidal grating, and
the amplitude is a physical height of a sinusoidal surface relief.

16. The laser optical lithography system of claim 12, wherein the computing device is further configured to set a film speed at which the film is to be moved in relation to the final desired linearly polarizing light.

17. The laser optical lithography system of claim 12, wherein:
the first quarter wave plate is configured to convert the linearly polarized light to the circularly polarized light at +45 degrees, and
the second quarter wave plate is configured to convert the elliptically polarized light from the SLM to the final desired linearly polarized light at −45 degrees.

18. The laser optical lithography system of claim 12, further comprising a camera configured to generate an image of the surface of the azopolymer film.

19. The laser optical lithography system of claim 12, wherein a grayscale value addressed to each pixel of the SLM is configured to generate a unique ellipticity at a spatial location of the pixel, as determined by a desired final polarization pattern to be projected onto the azopolymer film.

20. The laser optical lithography system of claim 12, wherein the final desired linearly polarized light is configured to print surface structures on the azopolymer film that diffract incident white light into red, green, and blue components.
